(19) United States
(12) Patent Application Publication
(10) Pub. No.: US 2007/0287289 A1
(43) Pub. Date: Dec. 13, 2007

(54) PRODUCTION METHOD OF CONDUCTIVE PATTERN

(76) Inventors: Toshio Haba, Tokai (JP); Hitoshi Suzuki, Hitachi (JP); Naohito Satou, Tokai (JP); Haruo Akahoshi, Hitachi (JP); Hiroshi Yoshida, Mito (JP); Akira Chinda, Hitachi (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/760,969

(22) Filed: Jun. 11, 2007

(30) Foreign Application Priority Data
Jun. 12, 2006 (JP) 2006-162704

(51) Int. Cl. H01L 21/44

(52) U.S. Cl. 438/687

(57) ABSTRACT

[Problem to be Solved] An object of the present invention is to provide a method of forming a conductive pattern having an excellent uniformity of film thickness within the surface of a substrate independently of the density of the pattern.

[Solution] The production method of a conductive pattern in accordance with the present invention comprises the step of electroplating for forming a conductive pattern by electroplating on a metal seed layer formed on an insulated substrate using a plating bath containing an accelerator for reducing the deposition overpotential of a plated metal.

### BACKGROUND OF THE INVENTION

1. Field of the Invention

The present invention relates to a method of producing a conductive pattern such as a pattern of wire lines and bumps.

2. Description of the Related Art

The demand for the downsizing, weight saving and price reduction of electronic devices are increasing year by year. Hence, it is required to produce a high-density conductive pattern at a low cost also for a wiring board used in electronic devices, in order to reduce the size and save the weight of the devices.

Methods of producing a conductor pattern are classified into two types. One is a subtractive method and the other is an additive method. In the subtractive method, an etching resist film is formed on a foil of copper adhered to a resin substrate, and by etching away the portions of the copper foil other than those to be formed into a conductive pattern, the conductive pattern is produced. In the additive method, a metal seed layer is formed on a resin substrate and the portions of the metal seed layer other than those to be formed into a conductive pattern is covered with a plating resist film, thereby forming plating films only in the portions to be formed into the conductive pattern.

The additive method is better suited for the production of a fine conductive pattern than the subtractive method. The subtractive method has the problem that dimensional accuracy of the pattern degrades since etching proceeds isotropically. The additive method does not have this problem since the dimensions of a pattern are dependent on a plating resist. However, the additive method also has a problem. Since the additive method requires a plating resist film having thickness same as that of a conductive pattern, the finer the pattern is, the more difficult it is to remove the plating resist between portions of the pattern. The process of removing the plating resist has been a bottleneck in producing the conductive pattern at a low cost.

Accordingly, there has been a desire for the development of a method of producing a conductive pattern without using a resist film-based mask or using a thin resist film. Under normal conditions, however, plating reaction proceeds isotropically like etching. Consequently, if plating thickness is increased in order to thicken the conductive pattern, the plating film also grows in the horizontal direction of a substrate, thus making it difficult to make the conductive pattern finer. To solve this problem, there has been proposed a method of anisotropically growing the plating film in the vertical direction of the substrate.

In Patent Document 1, a plating film is grown anisotropically by increasing plating current density to produce a printed circuit board.

In Patent Document 2, a conductive pattern is formed using a plating bath containing a nitrogen-containing organic substance and a sulfur-based organic substance.

In Patent Document 3, a plating film is grown anisotropically by setting the agitation speed of a plating bath to 0.01 to 0.1 m/s, the current density to 5 to 10 A/dm², and the metal ion concentration to 0.01 to 0.4 mol/liter.

In Patent Document 4, a plating film is grown anisotropically by adding a liquid viscosity adjuster to a plating bath to reduce the diffusion rate of copper ions in the plating bath, thereby decreasing a diffusion-limited current.

Patent Document 1: JP Patent Publication (Kokai) No. 60-230993A (1985)

Patent Document 2: JP Patent Publication (Kokai) No. 4-143289A (1992)

Patent Document 3: JP Patent Publication (Kokai) No. 11-100690A (1999)

Patent Document 4: JP Patent Publication (Kokai) No. 2005-126777A (2005)

### DISCLOSURE OF THE INVENTION

### Problems to be Solved by the Invention

In order to produce a fine conductive pattern without using a resist film-based mask or using a thin resist film while keeping the conductive pattern as thick as or thicker than the resist film, a plating film must be grown anisotropically in the vertical direction of a substrate. As a method of anisotropically growing the plating film in the vertical direction of a substrate, there is mainly used a method of performing plating on the condition that the reaction of copper deposition is the diffusion-limited reaction of copper ions. Plating conditions whereunder the reaction of copper deposition is the diffusion-limited reaction of copper ions include increasing the plating current density, decreasing the agitation speed of the plating bath, and increasing the viscosity thereof.

However, a method wherein the diffusion-limited reaction of copper ions is used for the anisotropic growth of a plating film has the problem that the variation of film thickness is large in a pattern of varied density. This is because the reaction of copper deposition is more apt to be diffusion-limited reaction between portions of the pattern at locations where the pattern is dense, whereas the reaction of copper deposition is less apt to be diffusion-limited reaction at locations where portions of the pattern are isolated. In addition, if the plating current density is increased in an attempt to make the reaction of copper deposition serve as the diffusion-limited reaction of copper ions, there arises the problem that the variation of plating film thickness becomes large between portions of the pattern close to a power feeding section and portions of the pattern distant from the power feeding section within the surface of a substrate. Another problem is that it is difficult to equalize the agitation speed of the plating bath within the surface of the substrate and this difficulty also contributes to increasing the variation of plating film thickness.

Accordingly, it is an object of the present invention to provide a method of producing a conductive pattern having an excellent uniformity of film thickness within the surface of a substrate independently of the density of the pattern.

### Means for Solving the Problems

A production method of a conductive pattern in accordance with the present invention comprises the steps of:

forming a metal seed layer on an insulated substrate; and

electroplating wherein the conductive pattern is formed on the metal seed layer by electroplating using a plating bath containing an accelerator for decreasing the deposition overpotential of a plated metal.

Another production method of a conductive pattern in accordance with the present invention comprises the steps of:

pre-plating treatment wherein an insulated substrate, on the surface of which a metal seed layer is formed, is immersed in a treatment liquid containing an accelerator for decreasing the deposition overpotential of a plated metal; and

electroplating wherein the conductive pattern is formed on the metal seed layer by electroplating using a plating bath containing the accelerator, the concentration thereof being lower than that of the treatment liquid, or using a plating bath not containing the accelerator.

Yet another production method of a conductive pattern in accordance with the present invention comprises the steps of:

metal seed layer patterning so that a metal seed layer formed on an insulated substrate is patterned into a desired shape;

accelerator adsorption wherein an accelerator for decreasing the deposition overpotential of a plated metal is made to selectively adsorb to the upper surface of the patterned metal seed layer; and

electroplating wherein the conductive pattern is formed on the metal seed layer, to the upper surface of which the accelerator has been adsorbed, by electroplating using a plating bath not containing the accelerator.

An organic sulfur compound is preferred as the accelerator when forming a conductive pattern of copper or of a copper alloy and bis(3-sulfopropyul)disulfide, 3-mercapto-1-propane sulfonic acid, bis(2-sulfoethyl)disulfide, bis(4-sulfobuthyl)disulfide and the like are particularly preferred.

### ADVANTAGE OF THE INVENTION

According to the present invention, it is possible to form a fine conductive pattern uniformly within the surface of a substrate.

### BEST MODE FOR CARRYING OUT THE INVENTION

The feature of the production method of a conductive pattern in accordance with the present invention is that the growth rate of a plating film is made to be higher in the vertical direction of a substrate than in the horizontal direction thereof, i.e., that the plating film is grown anisotropically. To this end, electroplating is performed using a plating bath containing an accelerator which accelerates plating reaction and adsorbs to the surface of a metal seed layer. The effect of the accelerator in accelerating plating reaction can be confirmed by the fact that the deposition overpotential of metal decreases when the accelerator is added to the plating bath. Use of this accelerator makes it possible to make the coverage of the accelerator higher on the upper surface of a pattern formed by plating than on the side walls of a metal seed layer or the pattern formed by plating. With this difference in the coverage of the accelerator, it is possible to make the growth rate of the plating film higher in the vertical direction of the substrate than in the horizontal direction thereof.

Now, an explanation will hereinafter be made of the reason for the plating film growing anisotropically in the vertical direction of the substrate when plating is performed using a plating bath containing such an accelerator as described above. The reason for being able to achieve the anisotropic growth of the plating film using this accelerator is that it is possible to make the coverage of the accelerator higher on the upper section of the pattern than on the ends of a pattern including the side walls of a metal seed layer or of the pattern grown by plating. In a case where plating is performed using this accelerator, the accelerator uniformly adsorbs to the surface of the metal seed layer when a substrate is immersed in a plating bath. When plating is started, the plating film initially grows at the same rate in every location of the metal seed layer. The accelerator adsorbed to the surface of the metal seed layer prior to plating still continues to adsorb to the surface during plating treatment. Now, consider the coverage of the accelerator with regard to the upper surface and the ends of the pattern when plating proceeds. Since the plating film only grows in the vertical direction of the substrate on the upper surface of the pattern, the area of the upper surface of the pattern remains constant and unchanged. Consequently, the coverage of the accelerator remains constant on the upper surface of the pattern. On the other hand, since a cross-sectional curvature is large at the ends of the pattern, the direction in which the plating film grows ranges from the horizontal direction to the almost vertical direction of the substrate. A surface area therefore increases at the ends of the pattern as the plating film grows. Consequently, if the adsorbed amount of accelerator remains unchanged, the accelerator coverage decreases by as much as the increment of the surface area at the ends of the pattern. Since this accelerator facilitates plating reaction, the growth rate of the plating film increases as the accelerator coverage becomes higher. Accordingly, the growth rate of the plating film increases on the upper surface of the pattern where the accelerator coverage is relatively high. Under these circumstances, the plating film grows anisotropically in the vertical direction of the substrate.

In order to further grow the plating film anisotropically in the vertical direction of the substrate, it is only necessary to increase a difference in the accelerator coverage between the upper portions and the ends of a pattern. To increase the accelerator coverage in the upper portions of the pattern, surface roughness should be made larger on the upper surface of the metal seed layer than on the side walls thereof. In addition, the accelerator should be adsorbed to the metal seed layer prior to plating and plating should be performed using a plating bath not containing any accelerator or containing an accelerator the concentration of which is lower than that of an accelerator used in a process of having the accelerator adsorbed. If plating is performed using a plating bath not containing any accelerator, no additional amounts of accelerator are adsorbed in the course of growth of a plating film. It is thus possible to increase the difference in the accelerator coverage between the upper surface and the ends of the pattern. Furthermore, after bringing a substrate adsorbed with an accelerator into selective contact with the upper surface of the metal seed layer, plating should be performed using a plating bath not containing any accelerator or containing an accelerator the concentration of which is lower than that of an accelerator used in a process of having the accelerator adsorbed. In this case, since most of the accelerator initially adsorbs to the upper surface of the pattern, the difference in the accelerator coverage between the upper surface and the ends of the pattern becomes large.

In addition to the accelerator for accelerating plating reaction, a surfactant, such as polyethylene glycol or polypropylene glycol, may be added. This improves the wettability of the substrate and enables the uniform growth of the plating film.

When forming a conductive pattern of copper according to the production method of a conductive pattern of the present invention, bis(3-sulfopropyl)disulfide is particularly preferred as the accelerator. Particularly excellent results were obtained when the accelerator concentration was 1 to 30 mg/L and the plating current density was 0.5 to 5.0 A/dm². Particularly excellent results were also obtained when the width of a metal seed layer for forming a conductive pattern was 1 to 100 μm and the ratio of the thickness of the metal seed layer to the width thereof was 0.001 to 0.1. In a case where the roughness of the upper surface of the metal seed layer was made large, particularly excellent results were obtained when the arithmetic average roughness Ra specified by JISB0601 was 0.01 to 4 μm and the average length RSm of roughness curve factors was 0.005 to 8 μm.

### EXAMPLES

Examples of the present invention will hereinafter be described with reference to the accompanying drawings. First, a table summarizing the results obtained from Examples 1 to 10 and Comparative Examples 1 and 2 is shown in FIG. 6. The symbols shown in the “Accelerator Type” column of the table denote the chemical substances listed below:
A1: bis(3-sulfopropyl)disulfide
A2: 3-mercapto-1-propane sulfonic acid
A3: bis(2-sulfoethyl)disulfide
A4: bis(4-sulfobuthyl)disulfide
B1: polyethylene glycol (average molecular weight=2000)
B2: polypropylene glycol (average molecular weight=1000)

Now, an explanation will be made of the degree of anisotropic growth R with reference to FIG. 5. FIG. 5a shows a case where no resist film remains underneath a conductive pattern and FIG. 5b shows a case where a resist film remains underneath a conductive pattern.

In FIG. 5a, a numeral 51 denotes an insulated substrate, a numeral 52 denotes a metal seed layer, and a numeral 53 denotes a conductive pattern. A symbol T1 denotes the thickness of the metal seed layer 52, a symbol W1 denotes the width of the metal seed layer 52, a symbol T2 denotes the wiring height of the conductive pattern 53 from the insulated substrate 51, and a symbol W2 denotes the wiring width of the conductive pattern 53. The degree of anisotropic growth R in this case is calculated as
R=(T2−T1)/((W2−W1)/2)

In FIG. 5b, a numeral 61 denotes an insulated substrate, a numeral 62 denotes a metal seed layer, a numeral 63 denotes a resist film, and a numeral 64 denotes a conductive pattern. A symbol T101 denotes the thickness of the metal seed layer 62, a symbol W101 denotes the width of the metal seed layer 62, a symbol T102 denotes the wiring height of the conductive pattern 64 from the insulated substrate 61, and a symbol W102 denotes the wiring width of the conductive pattern 64. The degree of anisotropic growth R in this case is calculated as
R=(T102−T101)/((W102−W101)/2)

Now, Example 1 is described. FIG. 1 is a cross-sectional view illustrating a method of producing a substrate having a conductive pattern in accordance with the present invention. As shown in FIG. 1a, a 0.05 μm thick nickel film and a 0.1 μm thick copper film were formed by sputtering on the surface of an insulated substrate 11 made of a 25 μm thick polyimide film substrate (Kapton EN made by Du Pont-Toray Co., Ltd.) as a metal seed layer 12. As the material of the insulated substrate, a resin such as polyester, glass epoxy, phenol or aramid, or ceramics, glass or the like may be used without limitation to polyimide. As shown in FIG. 1b, a resist film 13 was formed on the metal seed layer 12 deposited by sputtering and a 10 μm wide pattern was formed by photolithography. As shown in FIG. 1c, after etching the metal seed layer 12, the resist film 13 was removed to form the patterned metal seed layer 12. Copper in the metal seed layer 12 was etched using Mec Bright made by Mec Co., Ltd. and then nickel therein was removed using Mec Remover also made by Mec Co., Ltd. As a method of forming the metal seed layer 12, electroless plating, chemical vapor deposition (CVD) or the like may be used without limitation to sputtering. A metal seed layer formed by sputtering is not limited to a laminated film made of nickel and copper, but a laminated film made of chromium and copper or the like may be used. The thickness and width of the metal seed layer 12 thus formed were 0.15 μm and 10 μm, respectively, and the ratio of the thickness to the width was 0.015. Ra of the upper surface of the metal seed layer 12 was 0.01 μm, Ra of the side surfaces thereof was 0.007 μm, RSm of the upper surface thereof was 2 μm, and RSm of the side surfaces thereof was 2.5 μm. As shown in FIG. 1d, electroplating was performed to form a conductive pattern 14. As an electroplating bath, a solution wherein the substances shown in the table of FIG. 6 were added as accelerators to the constituents shown in the table of FIG. 7 was used. The plating time was set to 25 minutes, the current density was set to 1.0 A/dm², the temperature of the plating bath was set to 25° C., and a phosphorus copper plate was used as the anode. After plating, the cross-section of the conductive pattern 14 was observed and the wiring height and wiring width thereof were measured. The degree of anisotropic growth R calculated from the results of measurement was 3.0. The degree of anisotropic growth R was calculated as explained earlier with reference to FIG. 5a. In addition, the measured variation of the plating film thickness of the conductive pattern 14 within the surface of the substrate was ±3.1%. From the results described above, it was possible to produce a substrate having excellent uniformity within the surface of the substrate and having a fine conductive pattern by anisotropically growing the plating film in the vertical direction of the substrate.

Now, Example 2 is described. FIG. 2 is a cross-sectional view illustrating a method of producing a substrate having a conductive pattern in accordance with the present invention. As shown in FIG. 2a, a metal seed layer 22 was formed by depositing copper to a thickness of 0.05 μm by sputtering on the surface of an insulated substrate 21 made of a 25 μm thick polyimide film substrate (Kapton EN made by Du Pont-Toray Co., Ltd.). As shown in FIG. 2b, a resist film 23 was formed on the metal seed layer 22 and a pattern was formed by photolithography in such a manner that the 5 ∥m wide metal seed layer 22 was exposed. The thickness and width of the metal seed layer 22 thus formed were 0.05 μm and 5 μm, respectively, and the ratio of the thickness to the width was 0.01. Ra of the upper surface of the metal seed layer 22 was 0.01 μm, Ra of the side surfaces thereof was 0.007 μm, RSm of the upper surface thereof was 2 μm, and RSm of the side surfaces thereof was 2.5 μm. Then, the insulated substrate 21 on the surface of which the metal seed layer 22 and the resist film 23 were formed was immersed for 2 minutes in a pretreatment liquid shown in the table of FIG. 8. As shown in FIG. 2c, electroplating was performed immediately after the completion of immersion in the pretreatment liquid to form a conductive pattern 24. As an electroplating bath, the solution shown in the table of FIG. 8 was used. The plating time was set to 25 minutes, the current density was set to 1.0 A/dm², the temperature of the plating bath was set to 25° C., and a phosphorus copper plate was used as the anode. As shown in FIG. 2d, the resist film 23 was removed after plating and copper films other than the conductive pattern 24 and the metal seed layer 22 were removed by etching. After plating, the cross-section of the conductive pattern 24 was observed and the wiring height and wiring width thereof were measured. The degree of anisotropic growth R calculated from the results of measurement was 3.2. The degree of anisotropic growth R was calculated as explained earlier with reference to FIG. 5b. In addition, the measured variation of the plating film thickness of the conductive pattern 24 within the surface of the substrate was ±2.7%. From the results described above, it was possible to form a substrate having excellent uniformity within the surface of the substrate and having a fine conductive pattern by anisotropically growing the plating film in the vertical direction of the substrate.

Now, Example 3 is described. FIG. 3 is a cross-sectional view illustrating a method of producing a substrate having a conductive pattern in accordance with the present invention. First, as shown in FIG. 3a, a 3 μm thick copper foil was adhered as a metal seed layer 32 to the surface of an insulated substrate 31 made of a polyimide film substrate (Kapton EN made by Du Pont-Toray Co., Ltd.). Next, as shown in FIG. 3b, a resist film 33 was formed on the metal seed layer 32 and a 20 μm wide wiring pattern was formed by photolithography. As shown in FIG. 3c, after etching the metal seed layer 32, the resist film 33 was removed to form the patterned metal seed layer 32. The thickness and width of the metal seed layer 32 thus formed were 2 μm and 20 μm, respectively, and the ratio of the thickness to the width was 0.1. Ra of the upper surface of the metal seed layer 32 was 0.01 μm, Ra of the side surfaces thereof was 0.007 μm, RSm of the upper surface thereof was 2 μm, and RSm of the side surfaces thereof was 2.5 μm. As shown in FIG. 3c, a sponge soaked with the pretreatment liquid shown in the table of FIG. 8 was prepared as a pretreatment substrate 34. As shown in FIG. 3d, the pretreatment substrate 34 was brought into contact with the surface of the metal seed layer 32 on the insulated substrate 31 for 2 minutes. At this point, the pretreatment substrate 34 was brought into contact with the surface of the metal seed layer 32 under such a low pressure as not to come into contact with the side walls of the metal seed layer 32. As shown in FIG. 3e, electroplating was performed immediately after the completion of contact with the pretreatment substrate 34, to form a conductive pattern 35. As an electroplating bath, the liquid shown in the table of FIG. 7 was used. The plating time was set to 25 minutes, the current density was set to 1.0 A/dm², the temperature of the plating bath was set to 25° C., and a phosphorus copper plate was used as the anode. After plating, the cross-section of the conductive pattern was observed and the wiring height and wiring width thereof were measured. The degree of anisotropic growth R calculated from the results of measurement was 3.6. The degree of anisotropic growth R was calculated as explained earlier with reference to FIG. 5a. In addition, the measured variation of the plating film thickness of the conductive pattern 35 within the surface of the substrate was ±4.0%. From the results described above, it was possible to form a substrate having excellent uniformity within the surface of the substrate and having a fine conductive pattern by anisotropically growing the plating film in the vertical direction of the substrate.

Now, Example 4 is described. FIG. 4 is a cross-sectional view illustrating a method of producing a substrate having a conductive pattern in accordance with the present invention. As shown in FIG. 4a, copper was deposited by electroless plating to a thickness of 0.1 μm as a metal seed layer 42 on the surface of an insulated substrate 41 made of a polyimide film substrate (Kapton EN made by Du Pont-Toray Co., Ltd.). As shown in FIG. 4b, a 1 μm thick resist film 43 was formed on the metal seed layer 42 and a pattern was formed by photolithography in such a manner that the 10 μm wide metal seed layer 42 was exposed. As shown in FIG. 4c, copper electroplating was performed to a thickness of 1 μm to increase the thickness of the metal seed layer 42 in the pattern section. If the metal seed layer is sufficiently thick, the thickness of the metal seed layer need not necessarily be increased. As shown in FIG. 4d, a rugged shape was formed on the surface of the metal seed layer 42 by copper roughening treatment. The copper roughening treatment was performed using MultiBond made by Japan MacDermid Co., Ltd. and using the steps shown in the table of FIG. 9. As a copper roughening liquid, Mec etch Bond made by Mec Co., Ltd., Circubond made by Shipley Far East Ltd., Alpha Prep made by Alpha Metals Japan Ltd. or the like may be used, in addition to the liquid mentioned above. In addition, sandblasting, polishing or the like may be used as the roughening treatment method. As shown in FIG. 4e, the resist film 43 and the portions of the metal seed layer 42 other than the pattern section were removed. Measurement of the surface roughness of the metal seed layer 42 after the removal of the resist film 43 and the portions of the metal seed layer 42 other than the pattern portions showed that the arithmetic average roughness Ra specified by JIS B0601 was 0.5 μm and the average length RSm of roughness curve factors was 1.0 μm. In addition, measurement of the surface roughness of the side walls of the metal seed layer 42 showed that the arithmetic average roughness Ra specified by JIS B0601 was 0.05 μm and the average length RSm of roughness curve factors was 8.5 μm. These results of measurement revealed that surface roughness was larger on the upper surface of the metal seed layer 42 than on the side walls thereof. As shown in FIG. 4f, electroplating was performed to form a conductive pattern 44. As an electroplating bath, a solution wherein the substances shown in the table of FIG. 6 were added as accelerators to the constituents shown in the table of FIG. 7 was used. The plating time was set to 25 minutes, the current density was set to 1.0 A/dm², the temperature of the plating bath was set to 25° C., and a phosphorus copper plate was used as the anode. After plating, the cross-section of the conductive pattern 44 was observed and the wiring height and wiring width thereof were measured. The degree of anisotropic growth R calculated from the results of measurement was 5.0. The degree of anisotropic growth R was calculated as explained earlier with reference to FIG. 5a. In addition, the measured variation of the plating film thickness of the conductive pattern 44 within the surface of the substrate was ±4.2%. From the results described above, it was possible to form a substrate having excellent uniformity within the surface of the substrate and having a fine conductive pattern by anisotropically growing the plating film in the vertical direction of the substrate.

In Examples 5 to 10, a substrate having a conductive pattern was formed in the same way as in Example 1, except that the accelerator, the concentration thereof and the plating current density were varied. After plating, the cross-section of the conductive pattern was observed and the wiring height and wiring width thereof were measured. The degree of anisotropic growth R calculated from the results of measurement was 3 or larger and the measured variation of the plating film thickness within the surface of the substrate was ±5% or smaller. The degree of anisotropic growth R was calculated as explained earlier with reference to FIG. 5a. From the results described above, it was possible to form a substrate having excellent uniformity within the surface of the substrate and having a fine conductive pattern by anisotropically growing the plating film in the vertical direction of the substrate.

In Comparative Example 1, plating was performed to form a substrate having a conductive pattern in the same way as in Example 1, except that the plating bath did not contain an accelerator. After plating, the cross-section of the conductive pattern was observed and the wiring height and wiring width thereof were measured. The degree of anisotropic growth R calculated from the results of measurement was 1.0. The degree of anisotropic growth R was calculated as explained earlier with reference to FIG. 5a. In addition, the measured variation of the plating film thickness within the surface of the substrate was ±22%. From the results described above, it was not possible to anisotropicaily grow the plating film without an accelerator, thus failing to form a substrate having a fine conductive pattern.

In Comparative Example 2, plating was performed and a substrate having a conductive pattern was formed in the same way as in Example 1, except that the thickness of the copper seed layer was 10 μm. After plating, the cross-section of the conductive pattern was observed and the wiring height and wiring width thereof were measured. The degree of anisotropic growth R calculated from the results of measurement was 1.0. In addition, the measured variation of the plating film thickness within the surface of the substrate was ±5.0%. From the results described above, it was not possible to anisotropically grow the plating film if the ratio of the thickness of the copper seed layer to the width thereof was large, thus failing to form a substrate having a fine conductive pattern.

Industrial Applicability

Since it is possible to form a fine conductive pattern without using a resist-based mask formed by photolithography or using a resist film thinner than the height of a conductive pattern, the present invention is applicable to the formation of wiring lines and bumps on a printed wiring board, the formation of metal meshes on an electromagnetic shielding film, and the like.

### BRIEF DESCRIPTION OF THE DRAWINGS

FIGS. 1a to 1d are cross-sectional views illustrating a method of producing a substrate having a conductive pattern in accordance with the present invention;

FIGS. 2a to 2c are cross-sectional views illustrating a method of producing a substrate having a conductive pattern in accordance with the present invention;

FIGS. 3a to 3e are cross-sectional views illustrating a method of producing a substrate having a conductive pattern in accordance with the present invention;

FIGS. 4a to 4f are cross-sectional views illustrating a method of producing a substrate having a conductive pattern in accordance with the present invention;

FIGS. 5a and 5b are cross-sectional views intended to explain a method of evaluating a substrate having a conductive pattern;

FIG. 6 is a table summarizing the results obtained from Examples and comparative examples;

FIG. 7 is a table showing the constituents of an electroplating bath;

FIG. 8 is a table showing the constituents of an electroplating bath; and

FIG. 9 is a table showing the process of copper roughening treatment.

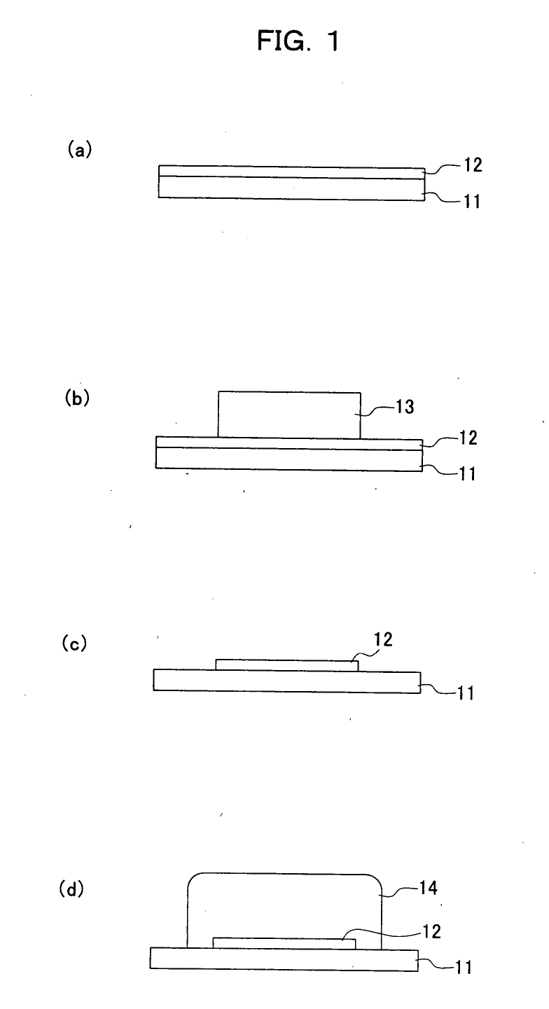

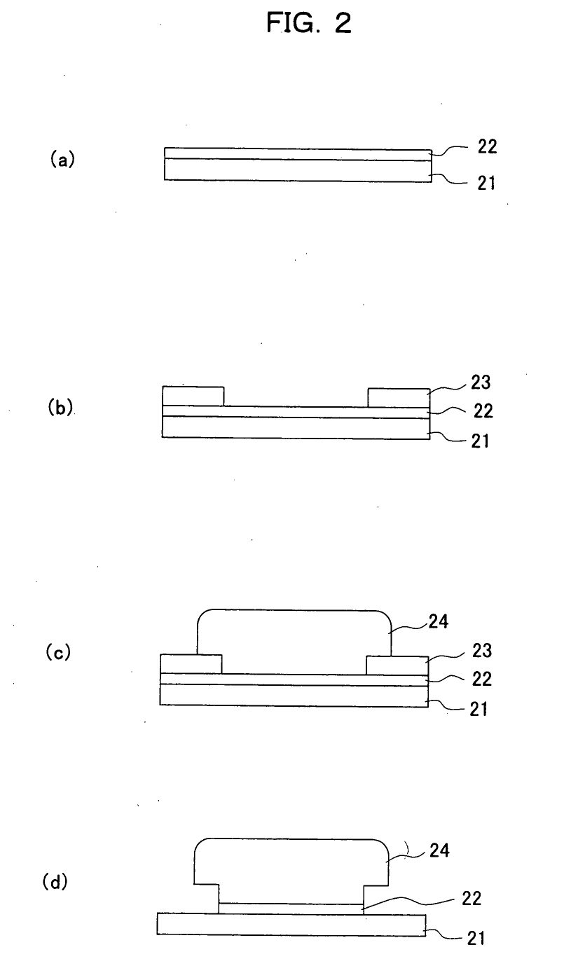

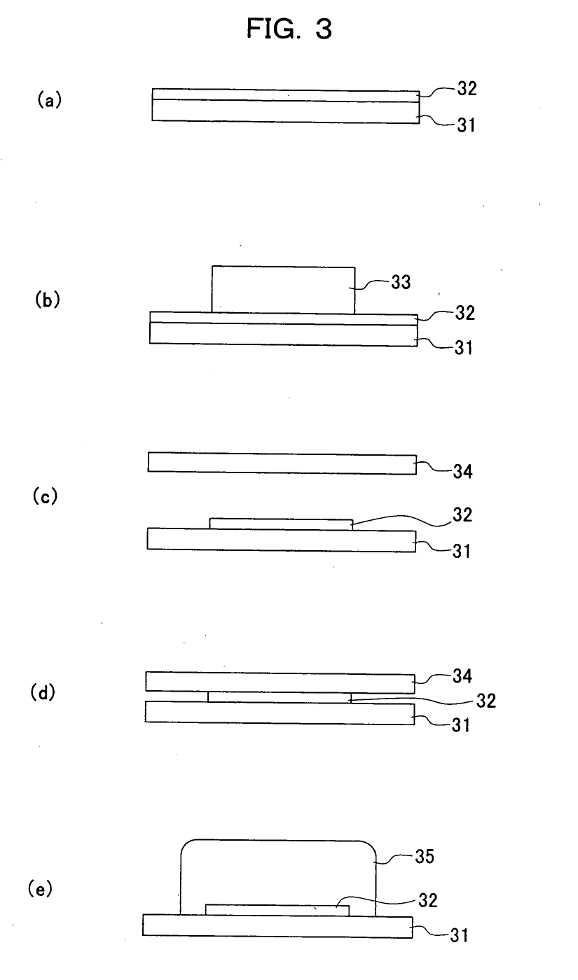

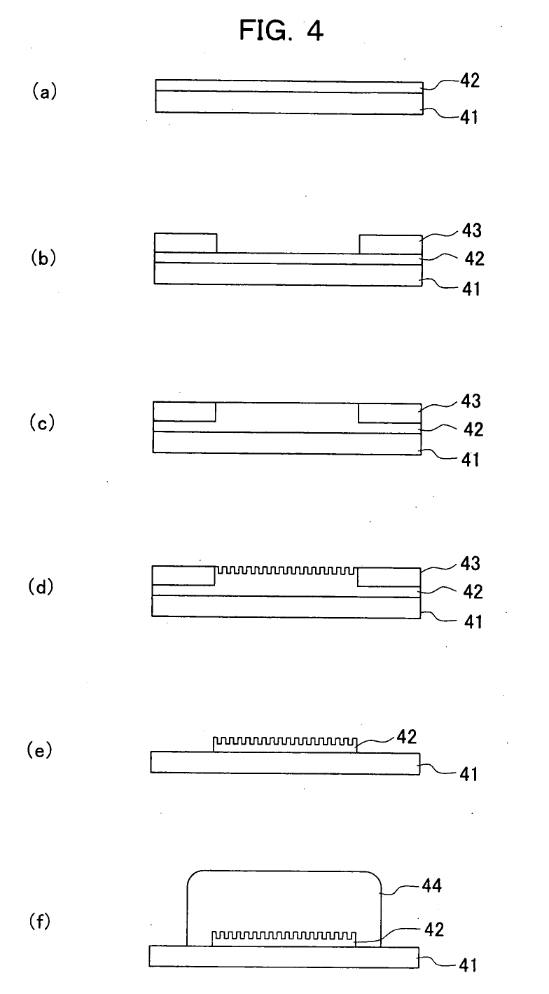

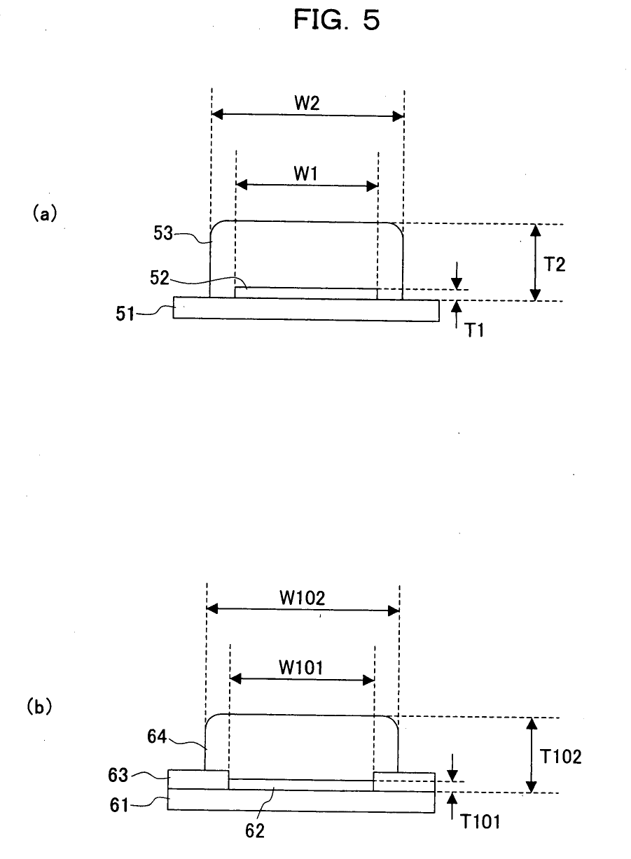

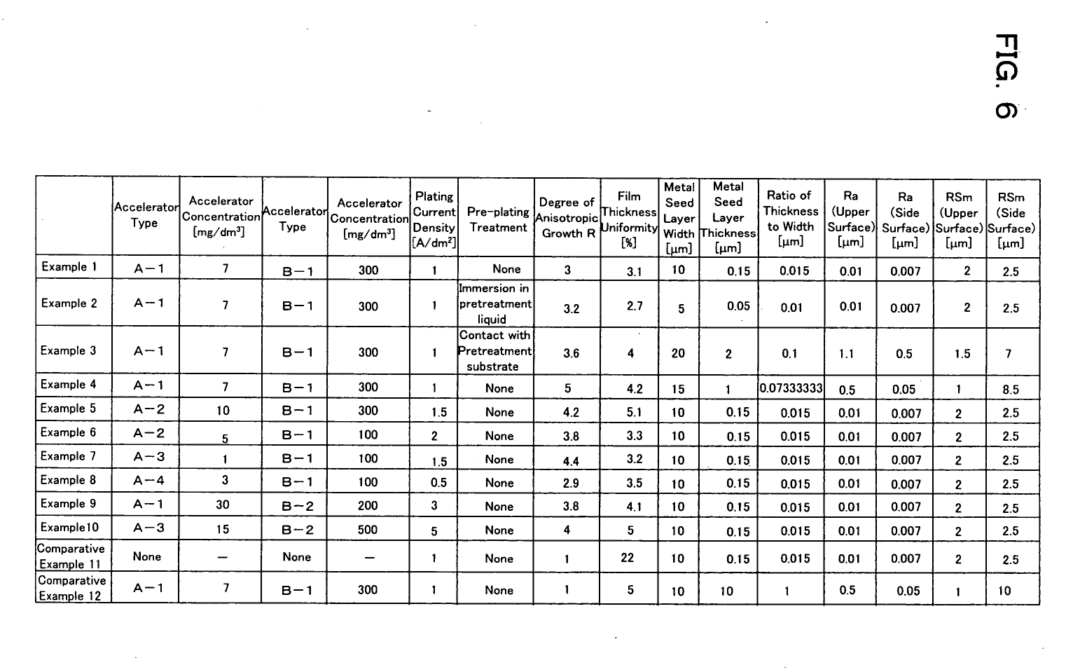

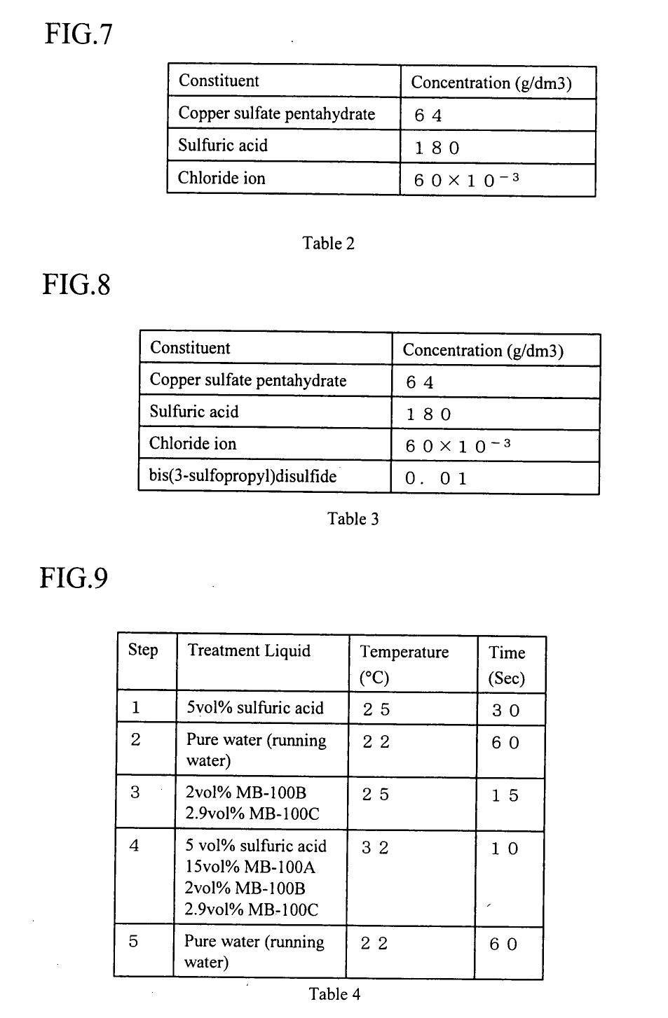

1. A production method of a conductive pattern, comprising the steps of:
forming a metal seed layer on an insulated substrate; and
electroplating wherein said conductive pattern is formed on said metal seed layer by electroplating using a plating bath containing an accelerator for decreasing the deposition overpotential of a plated metal.

2. A production method of a conductive pattern comprising the steps of:
pre-plating treatment wherein an insulated substrate, on the surface of which a metal seed layer is formed, is immersed in a treatment liquid containing an accelerator for decreasing the deposition overpotential of a plated metal; and
electroplating wherein said conductive pattern is formed on said metal seed layer by electroplating using a plating bath containing said accelerator, the concentration thereof being lower than that of said treatment liquid, or using a plating bath not containing said accelerator.

3. A production method of a conductive pattern comprising the steps of:
metal seed layer patterning so that a metal seed layer formed on an insulated substrate is patterned into a desired shape;
accelerator adsorption wherein an accelerator for decreasing the deposition overpotential of a plated metal is made to selectively adsorb to the upper surface of said patterned metal seed layer; and
electroplating wherein said conductive pattern is formed on said metal seed layer, to the upper surface of which said accelerator has been adsorbed, by electroplating using a plating bath not containing said accelerator.

4. The production method of a conductive pattern according to claim 3, wherein said step of accelerator adsorption comprises the step of bringing a treatment substrate soaked with said accelerator or a treatment substrate, to the surface of which said accelerator has been adsorbed, into contact with the upper surface of said metal seed layer.

5. The production method of a conductive pattern according to claim 1, further comprising the step of:
prior to said step of electroplating, metal seed layer roughening wherein the surface roughness of the upper surface of said metal seed layer is made larger than the surface roughness of the side walls of said metal seed layer.

6. The production method of a conductive pattern according to claim 5, wherein by said step of metal seed layer roughening, the average length of roughness curve factors RSm specified by JISB0601 is made smaller on the upper surface of said metal seed layer than on the side walls thereof or the arithmetic average roughness Ra specified by JISB0601 is made larger on the upper surface of said metal seed layer than on the side walls thereof.

7. The production method of a conductive pattern according to claim 1, wherein said electroplating is copper electroplating or copper alloy electroplating.

8. The production method of a conductive pattern according to claim 7, wherein said accelerator is an organic sulfur compound.

9. The production method of a conductive pattern according to claim 8, wherein said accelerator is bis(3-sulfopropyul)disulfide, 3-mercapto-1-propane sulfonic acid, bis(2-sulfoethyl)disulfide, or bis(4-sulfobuthyl)disulfide.

10. The production method of a conductive pattern according to claim 1, wherein said plating bath comprises a surfactant.

11. The production method of a conductive pattern according to claim 7, wherein said plating bath comprises copper sulfate pentahydrate and sulfuric acid.

12. The production method of a conductive pattern according to claim 2, wherein said electroplating is copper electroplating or copper alloy electroplating and said accelerator is bis(3-sulfopropyul)disulfide.

13. The production method of a conductive pattern according to claim 2, wherein said plating bath comprises a surfactant.

14. The production method of a conductive pattern according to claim 12, wherein said plating bath comprises copper sulfate pentahydrate and sulfuric acid.

15. The production method of a conductive pattern according to claim 3, wherein said electroplating is copper electroplating or copper alloy electroplating and said accelerator is bis(3-sulfopropyul)disulfide.

16. The production method of a conductive pattern according to claim 3, wherein said plating bath comprises a surfactant.

17. The production method of a conductive pattern according to claim 15, wherein said plating bath comprises copper sulfate pentahydrate and sulfuric acid.

18. A substrate having a conductive pattern formed on a metal seed layer by electroplating, wherein plating film thickness is larger in the vertical direction of said substrate than in the horizontal direction thereof and the ratio of the thickness of said metal seed layer to the width thereof is 0.001 to 0.1.

19. The substrate having a conductive pattern according to claim 18, wherein the width of said metal seed layer for forming said conductive pattern is 1 μm to 100 μm.

20. The substrate having a conductive pattern according to claim 18, wherein the arithmetic average roughness Ra specified by JISB0601 is larger on the upper surface of said metal seed layer than on the side walls thereof or the average length of roughness curve factors RSm specified by JISB0601 is smaller on the upper surface of said metal seed layer than on the side walls thereof.

21. The substrate having a conductive pattern according to claim 20, wherein the surface roughness of said metal seed layer is 0.01 to 4 μm in terms of the arithmetic average roughness Ra specified by JISB0601 and 0.005 to 8 μm in terms of the average length of roughness curve factors RSm specified by JISB0601.
